(19) United States
(12) Patent Application Publication
(10) Pub. No.: US 2012/0176803 A1
(43) Pub. Date: Jul. 12, 2012

(54) Light Emitting Diode (LED) Assembly and Method of Manufacturing the Same

(76) Inventor: Hamish McLennan, New South Wales (AU)

(21) Appl. No.: 13/411,759

(22) Filed: Mar. 5, 2012

(30) Foreign Application Priority Data
Sep. 10, 2009 (AU) 2009904337
Oct. 9, 2010 (AU) PCT/AU2010/001182

(51) Int. Cl. F21V 29/00; H01R 43/00; F28F 7/00; H05K 7/20; F21V 21/00

(52) U.S. Cl. 362/373; 361/720; 362/382; 165/185; 29/825

(57) ABSTRACT

The present invention relates to an improved light emitting diode (LED) assembly and method of manufacture which enables the fixing of LED chips to a much broader range of surfaces or objects, amongst other benefits. In particular, the invention relates to a metal core printed circuit board (MCPCB) including on a first surface an LED die, and on a second surface a heat spreader substrate. In a preferred embodiment, the MCPCB is a longitudinal rivet (or screw or the like) whereby the first surface is on the head of the rivet and the second surface extends along its length, the MCPCB rivet being adapted for quick and simple installation to a heat sink and/or PCB or MCPCB.

### FIELD OF THE INVENTION

The present invention relates to an improved light emitting diode (LED) assembly and method of manufacture which enables the fixing of LED chips to a much broader range of surfaces or objects, amongst other benefits. In particular, the invention relates to a metal core printed circuit board (MCPCB) including on a first surface an LED die, and on a second surface a conductive circuit layer. In a preferred embodiment, the MCPCB is in the shape of a longitudinal rivet (or screw or the like) whereby the first surface is on the head of the rivet and the second surface extends along its length, the MCPCB rivet thus being adapted for quick and simple installation to a heat sink and/or PCB or MCPCB.

### BACKGROUND OF THE INVENTION

The uses for LED's have grown quite considerably over the years, largely due to advances made in increases in their light output. Historically, the low light output from LED's made them impractical for use in applications requiring significant light output, for example, in outdoor applications, but there has been an increase in the employment of LED's as light source replacements in all light situations.

The apparent light output of an LED depends on a number of factors including the viewing angle of the LED with respect to the optical centre, and the brightness of the LED which itself depends on a number of factors. For example, the brightness can be affected by the amount of current being delivered to an LED, and the junction temperature of the LED. Keeping the junction temperature as low as possible maximises the performance potential of the LED.

A typical LED system comprises an emitter (which typically houses a LED die or chip, optics, encapsulent, and a heat sink plug), a metal-core printed circuit board (MCPCB), and some form of metal heat sink. One of the factors which affects the junction temperature of the LED and hence its performance is the effectiveness of the “thermal path”, that is, the path through which heat is moved away from the back side of the LED chip. Known thermal path designs involve the transfer of heat from the emitter to the MCPCB via a solder (if the emitter is soldered to the MCPCB), and from the MCPCB to the external heat sink (to which the MCPCB is usually mechanically attached), and finally to ambient surroundings.

An MCPCB is a type of circuit board comprising a metal substrate otherwise known as a heat spreader (typically copper or aluminium) and a dielectric layer which is a non-conductor of current. These boards, as the name suggests, are typically flat panels having a face for housing the LED as well as drive circuitry and components. Such components include, but are not limited to a voltage regulator, a current control and monitoring and feedback circuit, a temperature sensor, a light sensor, a moisture sensor, a dmx driver, a dmx receiver, a motion sensor, a resistor, a microcontroller, a shunt, a bypass controller and/or a communication link. The LED and associated circuitry and components can use up valuable space on circuit board faces. This space could otherwise be used to house more components, including more LED's for example.

It is becoming increasingly important to maximise efficiency, versatility and the use of confined spaces in LED lighting devices whilst still maintaining the required levels of heat transfer and performance.

It is therefore an object of the present invention to overcome at least some of the aforementioned problems or to provide the public with a useful alternative.

### SUMMARY OF THE INVENTION

Therefore in one form of the invention there is proposed a heat transfer device characterised by:

a body including a first surface and a second surface, said first and second surfaces extending in different planes;
a heat generating means associated with said first surface;
a means of transferring heat away from said heat generating means, said means of transferring heat being associated with said second surface.

Preferably said body is shaped in the form of a fastening means such as a rivet or screw, wherein a head portion of the fastening means includes said first surface, and an elongate body portion of the fastening means includes said second surface.

In preference said first surface and second surface are perpendicularly disposed.

Preferably said body is in the form of a printed circuit board (PCB).

In preference said body is in the form of a metal core printed circuit board (MCPCB), wherein said means of transferring heat includes said MCPCB metal core.

Preferably said means of transferring heat away from said heat generating means includes a heat conductive layer of material extending from said heat generating means on said first surface to said second surface.

In preference said heat generating means is a light emitting diode (LED).

In preference said heat conductive layer includes a circuit for transferring current to said LED.

Preferably said heat conductive layer include electrical components.

In preference said heat transfer device further includes a heat sink.

In a further form of the invention there is proposed a LED assembly characterised by:

a circuit board body including a first and second surface disposed in two different planes;
a LED chip associated with said first surface; and
a conductive circuit layer associated with said second surface, said conductive circuit layer being electrically connected to said LED chip.

Preferably said circuit board body includes an elongate shape, said first surface extending along an end of said elongate body, and second surface extending substantially perpendicularly along the length of the body.

In preference said circuit board body is in the shape of a fastener such as a rivet or screw including a head portion and a body portion having at least one flat surface, said LED chip being mounted to the head portion, and the circuit board body being mounted along said flat surface.

Preferably said circuit body is a metal core printed circuit board (MCPCB).

In preference said assembly further includes a heat sink.

In a further form of the invention there is proposed a terminal block adapted to house a LED assembly as characterised above.

In a yet further form of the invention there is proposed a light fixture adapted to house a LED assembly as characterised above.

In a still further form of the invention there is proposed a light fixture including:

an LED associated with an upper portion of an MCPCB elongate body;
a conductive circuit layer in electrical connection with said LED extending along the length of the MCPCB body;
a data/power cable associated with a lower portion of the MCPCB body in electrical connection with said conductive circuit layer; and
a heat sink.

In a further form of the invention there is proposed a method of manufacturing a LED assembly characterised by the step of forming a MCPCB body in the shape of a fastening means such as a rivet or screw including a LED manufactured on a head surface thereof, and a conductive circuit layer in electric connection with said LED and extending along the length of an elongate body portion surface of said fastening means.

In a still further form of the invention there is proposed a method of manufacturing a LED assembly characterised by the steps of:

(a) forming a MCPCB body in the shape of an elongate fastening means such as a rivet or screw;
(b) manufacturing a LED on an upper face of the elongate fastening means; and
(c) manufacturing a conductive circuit layer along a surface extending along the length of the elongate fastening means body.

In a yet further form of the invention there is proposed a LED assembly manufactured from the steps defined above.

### BRIEF DESCRIPTION OF THE DRAWING FIGURES

The accompanying drawings, which are incorporated in and constitute a part of this specification, illustrate several implementations of the invention and, together with the description, serve to explain the advantages and principles of the invention. In the drawings:

FIG. 1 illustrates a partially exploded perspective view of a rivet-type LED assembly in accordance with a first embodiment of the invention;

FIG. 2 illustrates an exploded perspective view of the LED assembly of FIG. 1;

FIG. 3 illustrates a side, partial cross-sectional view of the LED assembly of FIG. 1;

FIG. 4 illustrates a front, partial cross-sectional view of the LED assembly of FIG. 1;

FIGS. 5 to 19 illustrate front cross-sectional views of various LED assemblies embodying the present invention when fixed to alternately configured heat sinks;

FIG. 20 illustrates a plurality of LED assemblies fixed to a heat sink wafer in accordance with the present invention;

FIG. 21 illustrates a side cross-sectional view of the LED assembly of FIG. 1 fixed to another MCPCB;

FIGS. 22 to 29 illustrate side cross-sectional views of rivet-type LED assemblies according to further embodiments of the present invention;

FIGS. 30 to 43 illustrate top cross-sectional views of rivet-type LED assemblies according to still further embodiments of the present invention;

FIG. 44 illustrates a perspective view of a rivet-type LED assembly including electrical circuit components in accordance with a preferred embodiment of the invention;

FIG. 45 illustrates a perspective view of a terminal block;

FIG. 46 illustrates a top cross sectional view of the terminal block of FIG. 45;

FIG. 47 illustrates a perspective view of the terminal block of FIG. 45 when affixed to the LED assembly of the present invention;

FIG. 48 illustrates a side cross sectional view of the terminal block and LED assembly of FIG. 37;

FIG. 49 illustrates a perspective view of a RGB terminal block when affixed to a rivet-type LED assembly having an RGB conductive circuit layer;

FIG. 50 illustrates an exploded perspective view of FIG. 49;

FIG. 51 illustrates a side cross sectional view of the LED assembly and terminal block of FIG. 49 in a disengaged state;

FIG. 52 illustrates a side cross sectional view of the LED assembly and terminal block of FIG. 49 in an engaged state;

FIG. 53 illustrates a perspective view of an alternate type of RGB terminal block when affixed to a rivet-type LED assembly having an RGB-conductive circuit layer;

FIG. 54 illustrates an exploded perspective view of FIG. 53;

FIG. 55 illustrates a side cross sectional view of the LED assembly and terminal block of FIG. 53;

FIG. 56 illustrates a front cross sectional view of the LED assembly and terminal block of FIG. 53;

FIGS. 57 and 58 illustrate top cross sectional views of the LED assembly and terminal block of FIG. 53;

FIG. 59 illustrates a cutaway perspective view of an LED assembly housed in a puck device;

FIG. 60 illustrates the LED assembly of FIG. 59 with the puck housing removed;

FIG. 61 illustrates an exploded perspective view of the LED assembly and puck device of FIG. 59 associated with a hand rail heat sink;

FIG. 62 illustrates an exploded perspective view of a LED assembly, hand rail heat sink, and puck device according to a further embodiment;

FIG. 63 illustrates a perspective view of a plurality of LED assemblies connected through a heat pipe and heat sink apparatus;

FIG. 64 illustrates a perspective view of a reflector for use with the apparatus of FIG. 63;

FIG. 65 illustrates a perspective view of a power connecting junction with a LED assembly connected;

FIG. 66 illustrates a perspective view of a plug including a LED assembly fixed thereto;

FIG. 67 illustrates a perspective view of the LED assembly of FIG. 66;

FIG. 68 illustrates a perspective view of internal components of the plug of FIG. 66;

FIGS. 69 to 88 illustrate side views of rivet-type and screw-type LED assemblies according to still further embodiments of the invention;

### DETAILED DESCRIPTION OF THE PREFERRED EMBODIMENTS

The following detailed description of the invention refers to the accompanying drawings. Although the description includes exemplary embodiments, other embodiments are possible, and changes may be made to the embodiments described without departing from the spirit and scope of the invention. Wherever possible, the same reference numbers will be used throughout the embodiments and the following description to refer to the same and like parts.

The present invention relates to a LED assembly which in a broad form comprises a circuit board substrate including at least two surfaces disposed in different planes, a first surface having associated therewith an LED die or chip, and a second surface having associated therewith a conductive circuit layer electrically connected to the LED chip. The skilled addressee would realise that in providing a circuit board with the ability to fix an LED to a surface extending in one plane, and associated circuitry and components to a surface extending in a different plane, the overall dimension or footprint of the LED assembly 10 is reduced compared to using say a flat panel MCPCB. The invention further provides an improved thermal path from the LED to the ambient surroundings, and more versatility in that the circuit board configuration allows it to be any desired shape, for example in the shape of a rivet or screw.

It is to be understood that whilst the following description refers to the use of a MCPCB, other substrates could equally well be used such as a printed circuit board (PCB) for example. The invention is not intended to be limited to the embodied application only, as the same principles could equally well be applied to any environment involving the transfer of heat in a device.

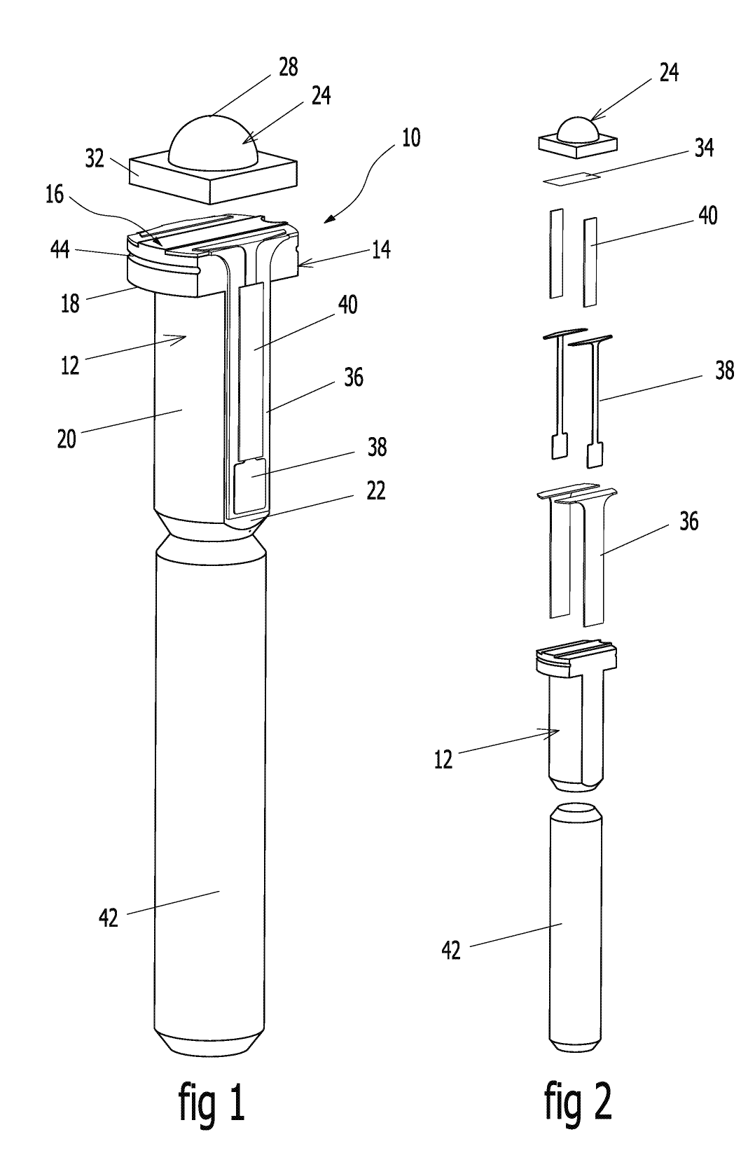

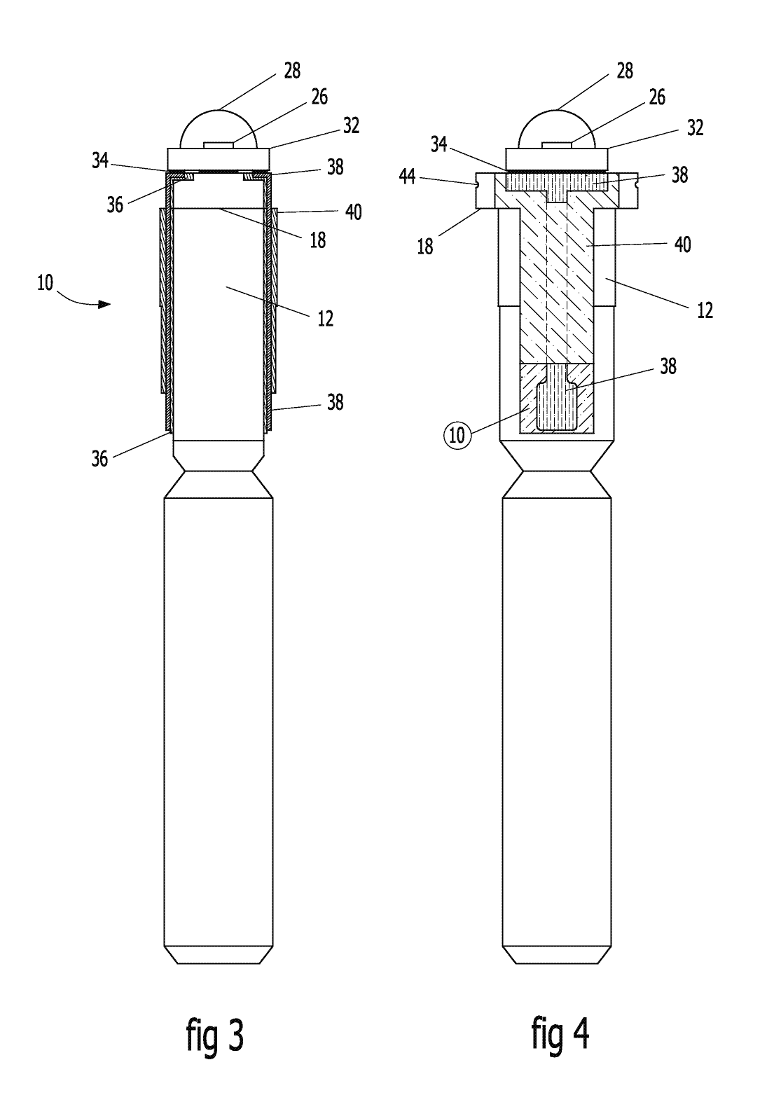

FIGS. 1-4 illustrate a rivet-shaped LED assembly 10 including a MCPCB 12 having a head portion 14 with a top face 16 and lower shoulder 18, and a longitudinal body portion 20 extending outwardly therefrom. The body portion 20 includes a flat surface 22 extending down along at least one side thereof and perpendicular to the top face 16, although other angles and arrangements are also possible.

Fixed to the top face 16 is an LED device 24 which is known in the art as a solid-state semiconductor device that converts electrical energy directly into light. On its most basic level, the semiconductor is comprised of two regions, the p-region which contains positive electrical charges, and the n-region which contains negative electrical charges. When voltage is applied and current begins to flow, the electrons move across the n-region into the p-region. The process of an electron moving through the p-n junction releases energy. The dispersion of this energy produces photons with visible wavelengths.

The LED device 24 includes an LED chip or die 26 which works on the above principle, an LED lens 28 which is a clear plastic cover that covers the LED to direct light, a LED reflector 30 (optional—shown in additional embodiments) which is a mirrored surface for reflecting light, and a LED board 32 which is a small printed circuit board that the LED chip 26 is manufactured on. It will also become apparent that the board 32 is not always necessary. In the embodiment shown, the LED chip 26 is thermally coupled and electrically connected on the rivet-shaped MCPCB top face 16 by way of a solder, using a soldering pad 34.

Inverted L-shaped non-conducting layers 36 are fixed to the MCPCB 12 such that the shorter length of each layer extends across the top face 16 and the longer length extends down along the flat surface 22. This layer forms a fixing membrane between two conducting (or non-conducting) materials or layers, in this case between the conductive MCPCB 12 and the similarly shaped conductive circuit layers or “heat spreaders” 38 which extend over the non-conducting layers 36. The conductive circuit layers 28 are typically copper and they form the circuitry layers for the MCPCB 12. The top face portions of the conductive circuit layers 28 are sometimes referred to as landings or islands to which the LED chips are mounted.

Also shown is an outer non-conducting layer 40 which is a thin film adapted to cover all the electric components 42 (not shown in FIGS. 1-4) that are commonly used on a PCB or MCPCB to protect them. This layer 40 is usually a high temperature epoxy or resin or glue which is capable of withstanding heat. The film may be thick where required and this is described in more detail below.

The rivet stem 43 forms an extension of the rivet-shaped MCPCB 12 and is removed when the rivet is fixed as is known in the art. The head portion 14 of the MCPCB 12 also includes a notch 44 which enables other items to be located and held onto the assembly. The MCPCB shoulder 18 is obviously used to prevent the rivet shaped MCPCB from being pulled through a hole through which the rivet extends, like an aperture associated with a heat sink for example. The shoulder 18 can also be used to accommodate an electrical connection between the rivet and an associated device.

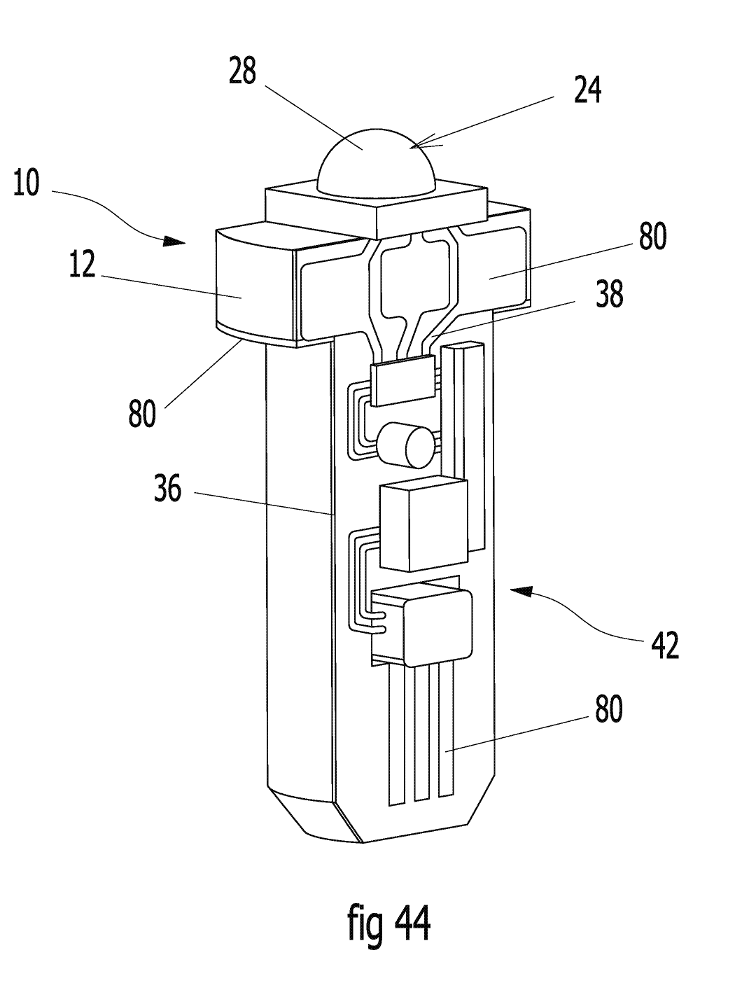

It is to be understood that the location and electrical requirements of the components that are to be used on the assembly 10 are not limited to the surface 22. They could be positioned through the MCPCB 12 as shown in FIG. 44, for example, to save space and/or to enable connection to multi-layered MCPCB or PCB circuitry or heat spreader substrates.

The skilled addressee would realise that the use of more than one surface of an MCPCB 12 (in this case being the edge or top face 16 of a rivet-shaped MCPCB) for mounting LED chip(s) or LED board(s) saves significant space and results in the overall dimension (diameter) of the assembly to be extremely compact. This is very important in lighting situations in confined spaces.

In being able to provide MCPCB's in the shape of rivets and screws, the invention enables extremely quick and simple installation of the LED to a heat sink 46 and/or a PCB or MCPCB as only an appropriately dimensioned aperture is required to install the LED, or group of LED's, to the fixture. The invention is not intended to be limited to this fixing method as the shapes could also be made to fit over the edge of such fixtures, or even on their surface. Further still, the MCPCB could be shaped to accommodate heat pipes, thermoelectric coolers, and other components. The MCPCB 12 acts as a thermal mediator between the LED board and the heat sink 46, providing a larger heat transfer footprint for the LED, as well as assisting in the ease of assembly, for example, associated wiring.

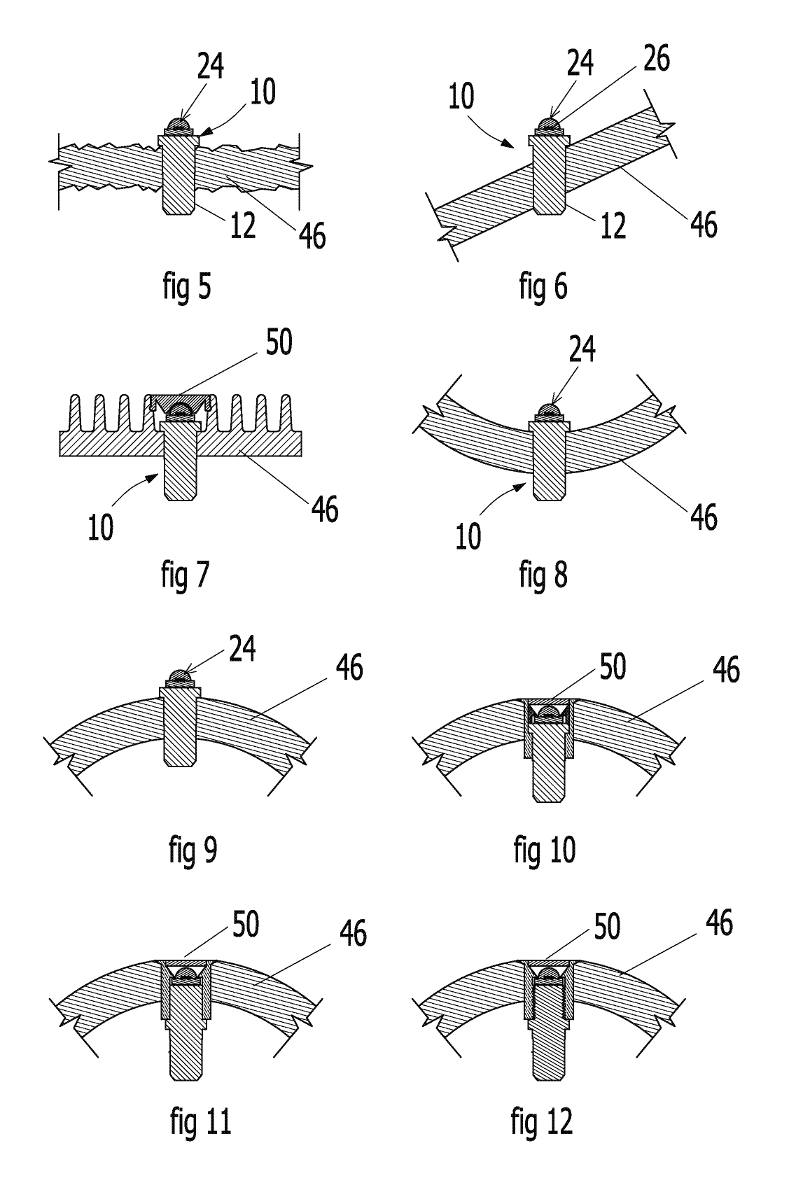

FIGS. 5-19 illustrate the LED assembly 10 of the present invention, according to several embodiments, having associated therewith a heat sink 46 which those skilled in the art would know is used to remove heat produced by the LED chip and its components. The heat sink 46 can be connected to the LED assembly a number of different ways and this is evident in the different examples provided. The present invention is not intended to be limited to any one heat sink arrangement. Each embodiment will now be described briefly. Whilst all the heat sinks shown are configured differently, they are each referenced using the same numeral for the purpose of brevity.

FIG. 5 shows the LED assembly 10 fixed to a rough surface heat sink 46. FIG. 6 shows the assembly 10 fixed through a heat sink 46 at an angle. FIG. 7 illustrates the assembly 10 sunken into a small space between heat sink fins 48 and includes an additional lens 50 affixed to the fins 48, demonstrating yet another possible configuration. FIG. 8 shows the LED assembly 10 fixed to an internal radius curved surface heat sink 46, whilst FIG. 9 shows the LED assembly 10 fixed to an external radius curved heat sink 46.

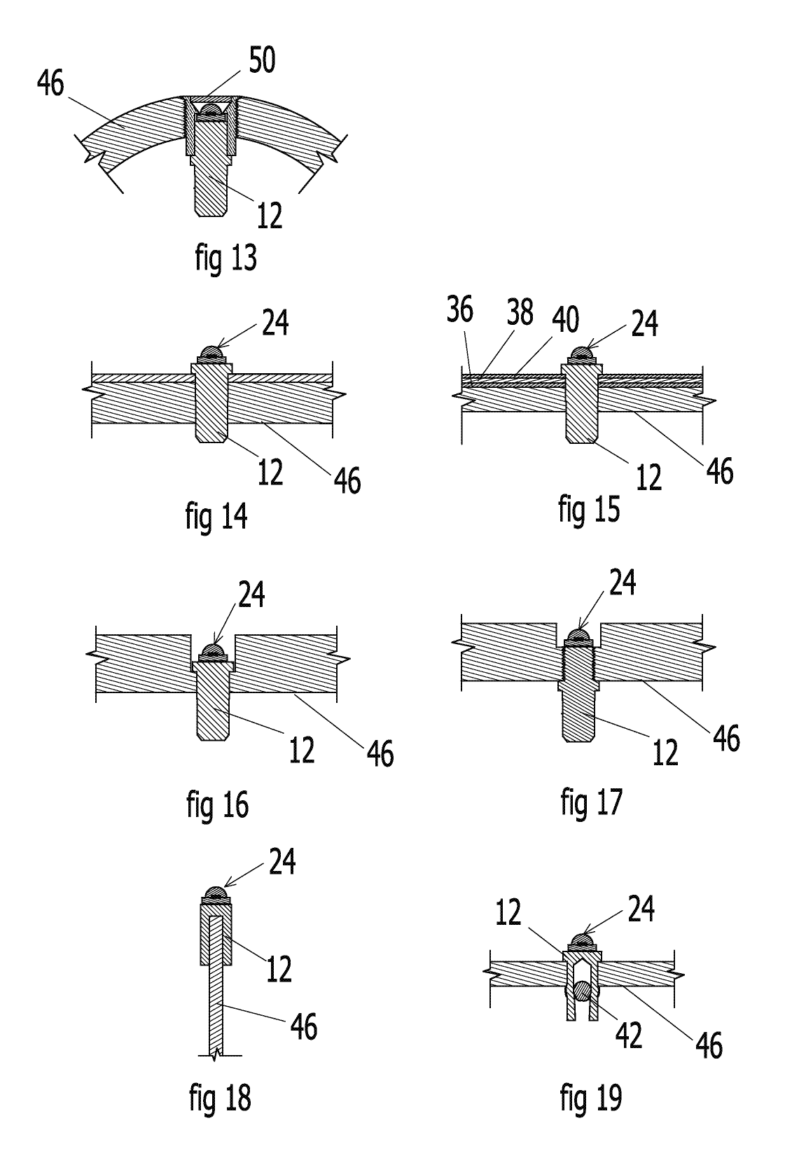

FIGS. 10, 11, 12 and 13 illustrate LED assemblies 10 again including rivet-shaped MCPCB's, which are fixed with sleeves 51 to lower the MCPCB into the heat sink (these examples show curved heat sinks, but the use of sleeves should not be limited to this). In the embodiments of FIGS. 10-12, the shoulder of the MCPCB 12 is located at an opposite end being the lower portion to suit the particular heat sink configuration. The assembly 10 of FIG. 12 includes an MCPCB having a threaded outer surface and so forms a bolt-type MCPCB rather than a rivet-type. FIG. 13 shows an alternately configured sleeve including an outer thread.

A full description of the way in which each of these components is connected, for example, by threaded connection, or by interference fit, etc, is not provided because it is considered known in the art.

The assembly 10 of the present invention could also be used to hold together various components as shown in FIGS. 14-15. In particular, FIG. 14 shows a LED assembly 10 holding together a heat sink 46 and a reflective panel 30. FIG. 15 illustrates the assembly 10 holding together a heat sink 46 and a printed circuit board 54.

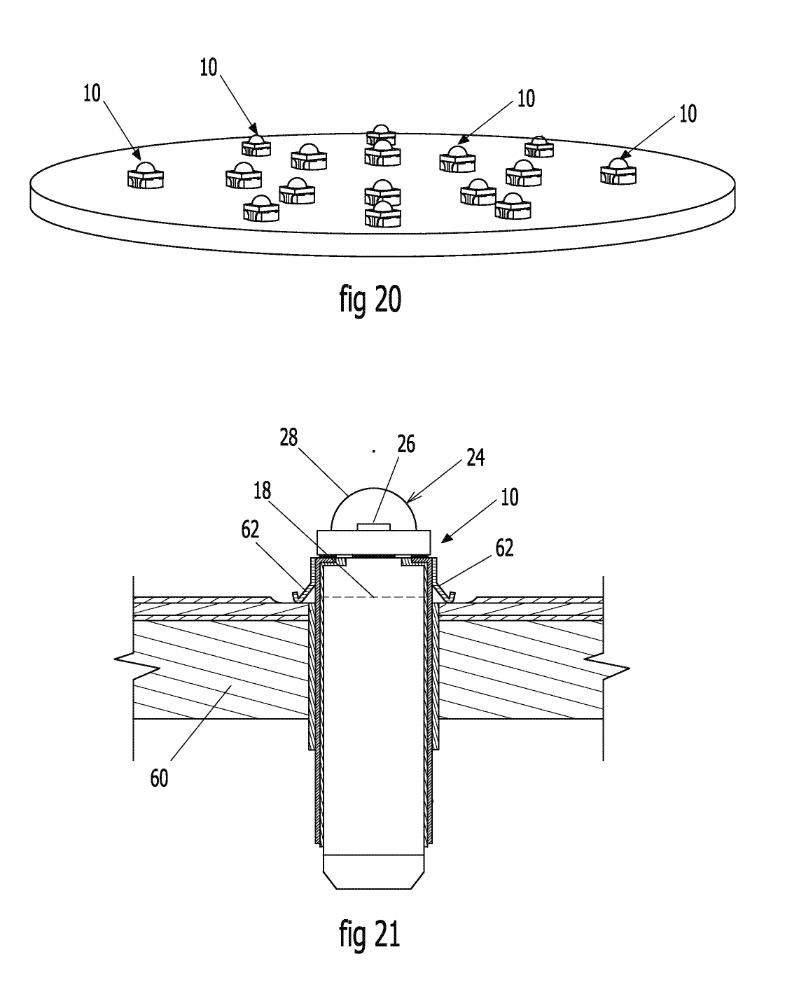

FIGS. 16-19 show yet further embodiments in the form of a LED assembly 10 fixed to a recessed heat sink 46 in FIG. 16, an assembly 10 threaded to a recessed heat sink 46 in FIG. 17, a LED assembly 10 having a rivet-shaped MCPCB 12 with a slot 56 to fit over the heat sink 46, and an assembly 10 fixed to a heat sink 46 through the distortion of the rivet, that is, through use of the remaining rivet stem 42. FIG. 20 illustrates a heat sink wafer 58 including multiple apertures for receiving a plurality of LED assemblies 10.

FIG. 21 is similar to FIG. 15 in that it shows an LED assembly 10 housed in another MCPCB 60. This drawing however demonstrates the use of circuit connection clips 62 which may be added to the rivet-shaped MCPCB 12 to enable circuit connections to the other MCPCB 60.

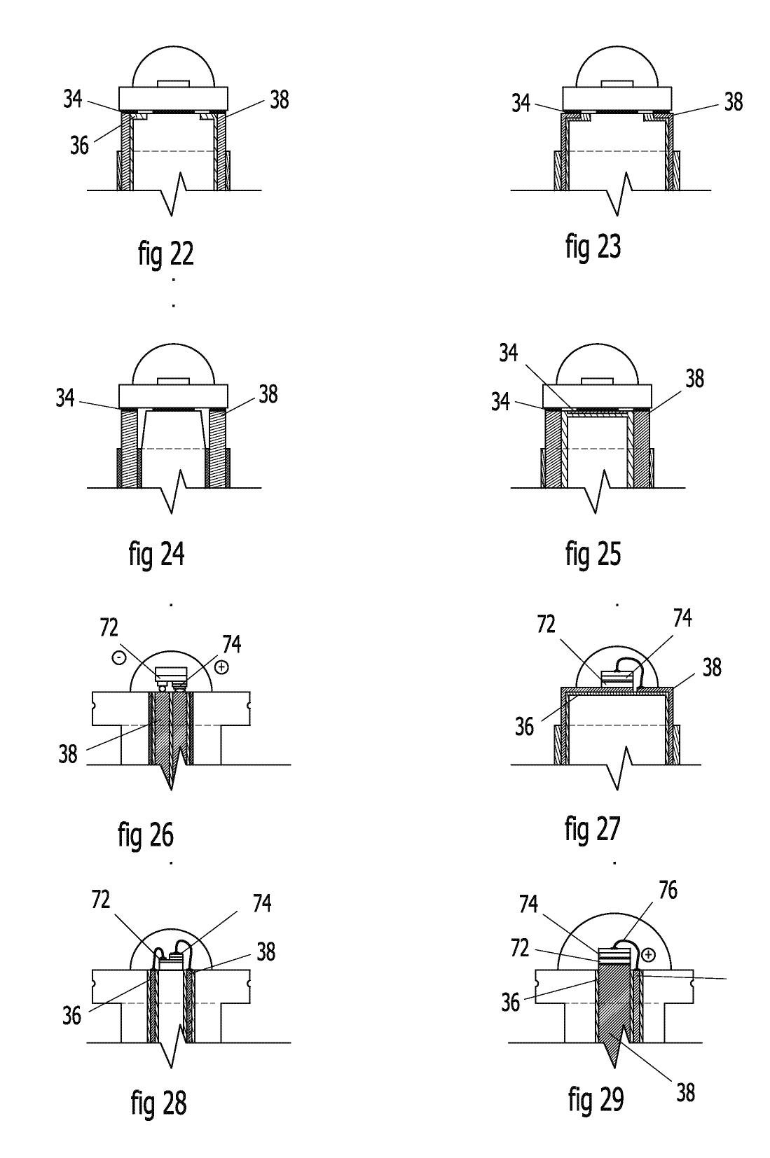

FIGS. 22-25 illustrate how the conductive circuit layer 38 can be configured a number of different ways. For example, FIG. 22 shows the conductive layer 38 extending along the body up to the solder pad 34, and FIG. 23 shows the conductive layer 38 extending up the body of the MCPCB 12 with a perpendicular bend to align with the solder pad 34. FIG. 24 shows the conductive layer as a wire (for power or data transporting medium) running alongside the body of the rivet-shaped MCPCB up to the solder pad 34. FIG. 25 illustrates how an additional solder pad 64 could be employed to create a thermal path from the LED to an aluminium rivet body.

As mentioned earlier, the LED chip 26 needn't necessarily have an associated LED board 32. FIGS. 26-31 illustrate examples of LED assemblies which are configured like so, that is, without a board 32 and with an LED chip 24 and lens 28 affixed to the rivet 12. The shape and size of the MCPCB 12 thus eliminates the need for several components because the positive and negative doped chip can be affixed directly to the board 12.

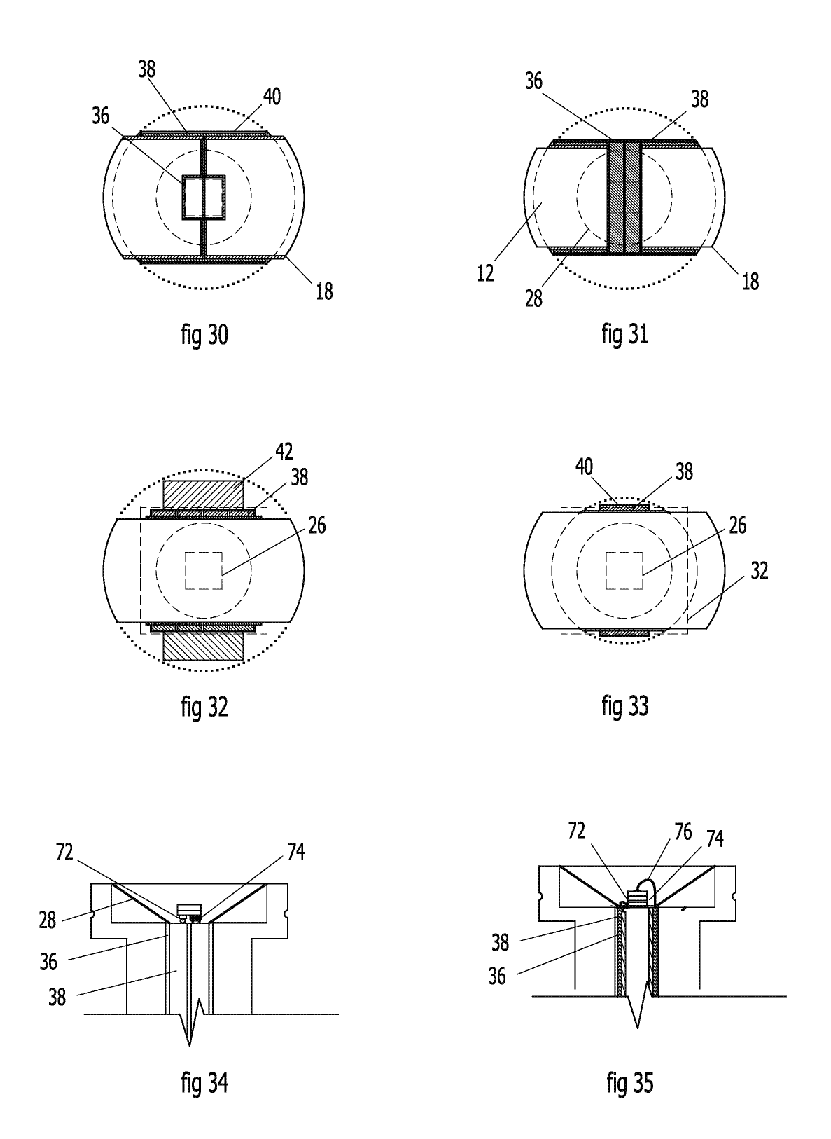

FIG. 26 shows an assembly 10 wherein an LED is fixed to a positive 66 and a negative 68 of the conductive circuit layers 38 that run along the length of the MCPCB 12 and which transfer heat directly away from the LED chip 24. FIG. 27 illustrates how the LED chip 24 could be fixed to a rivet 12 with a non-conductive material 36 there between, and a circuit layer 38 extending from the sides of the rivet to a negative doped chip 72 and a positive doped chip 74. Similarly, FIG. 28 shows a LED assembly 10 including a LED chip 24 fixed to the rivet 12 with a non-conductive material 38 there between, but with a circuit layer extending through the rivet 12 to a negative doped chip 72 and positive doped chip 74. Shown in FIG. 29 is an LED chip 24 fixed to the conductive circuit layer 38 which extends along the length of the MCPCB 12 and can transfer heat directly away from the LED chip 24. A wire bond 76 is used to provide an electrical connection between the negative doped chip 72 and positive doped chip 74. FIG. 30 shows an LED assembly 10 including an LED chip 24 affixed to the rivet 12, and a conductive circuit layer and heat transfer path 38 in the centre of the rivet 12. FIG. 31 shows an LED chip 24 mounted directly to electrically conductive heat spreaders forming the conductive circuit layer 38.

FIGS. 32 to 35 illustrate still further embodiments using a LED board 32, namely, a LED assembly 10 with electrical components 42 connected to the circuit and a LED assembly 10 with conductive circuit layers 38 extending up the sides of the rivet 12.

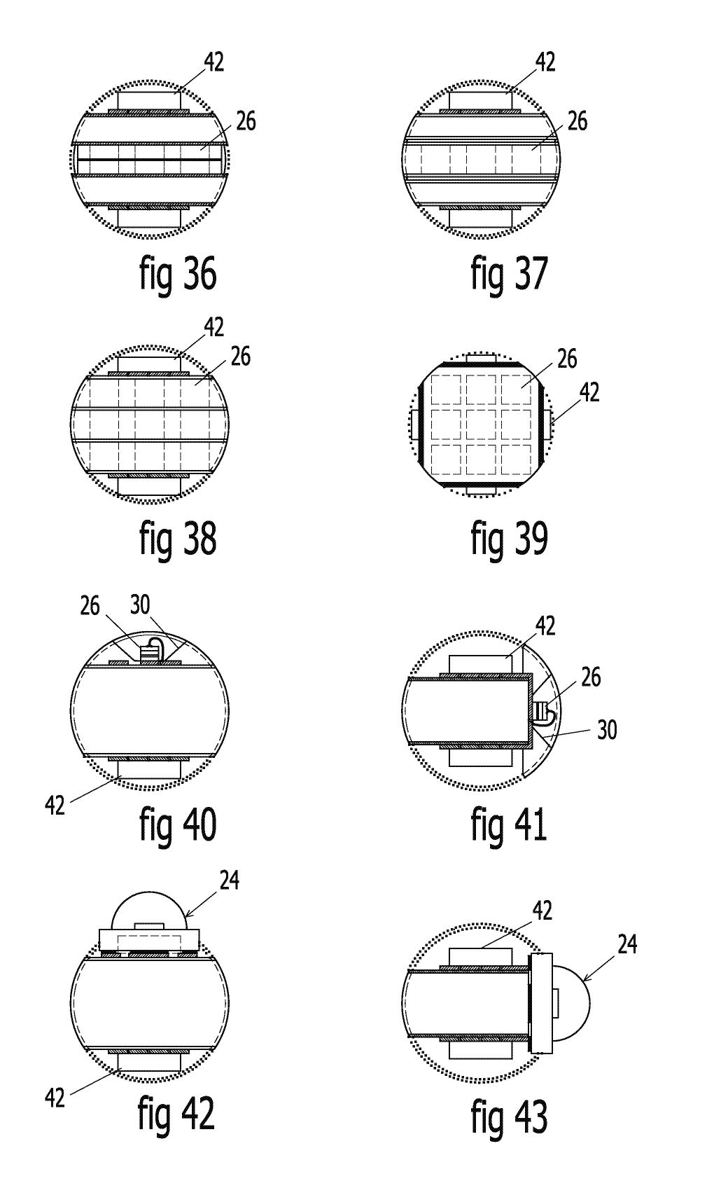

Yet further possible embodiments are shown in FIGS. 36 to 43. FIGS. 36 to 39 show LED assemblies having multiple LED chips 24 mounted, FIGS. 40 and 41 illustrate LED assemblies 10 having a LED chip mounted along the side of the rivet, and assemblies 10 having a LED board 32 mounted to the side of the rivet are shown in FIGS. 42 and 43.

In each of FIGS. 30-43, the outer non-conducting layer is a thick coating which encapsulates the circuitry and components and fills the shape out from a rectangle to a circle, although other shapes are possible.

Thus, the conductive layer 38 is used to house the electrical circuit and components 42 that would be used on the MCPCB, and may include a voltage regulator, current control circuit and monitoring and feedback circuit, temperature sensor, a light sensor, a moisture sensor, a dmx driver, a dmx receiver, a motion sensor, a resistor, a microcontroller, a shunt, a bypass controller, a sensor of any type, and/or a communication link. Some of these components are shown in more detail in the LED assembly 10 of FIG. 34. Also present are power data connection areas 80 to which power or data wires can be connected. The skilled addressee would realise that such an assembly provides a number of advantages, including:
there is no limitation on where the power or data can be connected to the device as the MCPCB can be designed for any particular area, thus allowing for a broader amount of connection options (for example, the clips 62 shown in FIG. 21 show but one connection option at the top of the rivet 12);
any circuitry components including those mentioned above can be placed on the faces of the MCPCB 12;
the components can be housed through the device, to save space, to bridge, or to make contact with circuitry on the other side;
the circuitry is not limited to one layer—it can be multi-layered;
the circuitry (wiring substrate) can be 3-dimensional;
the circuitry and the components can be covered in protective epoxy resin sealant, as mentioned earlier, or silicone or the like to water proof and/or insulate the circuitry and components thermally and electrically;
the sealing of the circuitry and components can be a thin coating just to seal or insulate;
the sealing can also be a thick coating to encapsulate the circuitry and components to fill the shape out from one shape to another, for example, form a rectangle to a circle as per FIGS. 30-33; and
the coating encapsulate can also assist in the formation of threads, shoulders, etc.

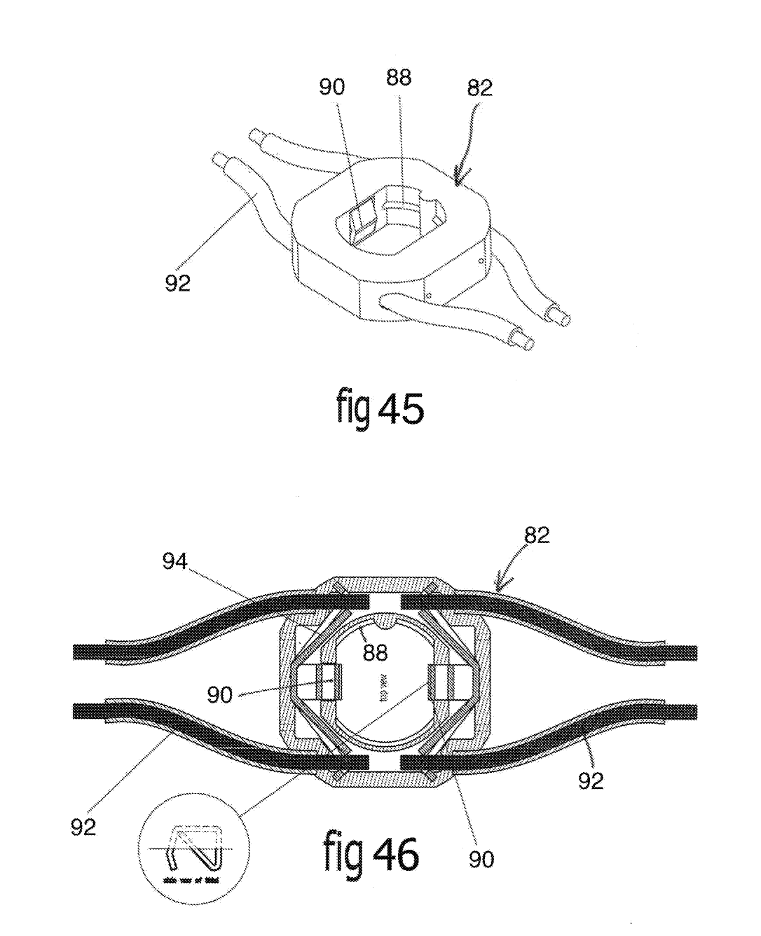

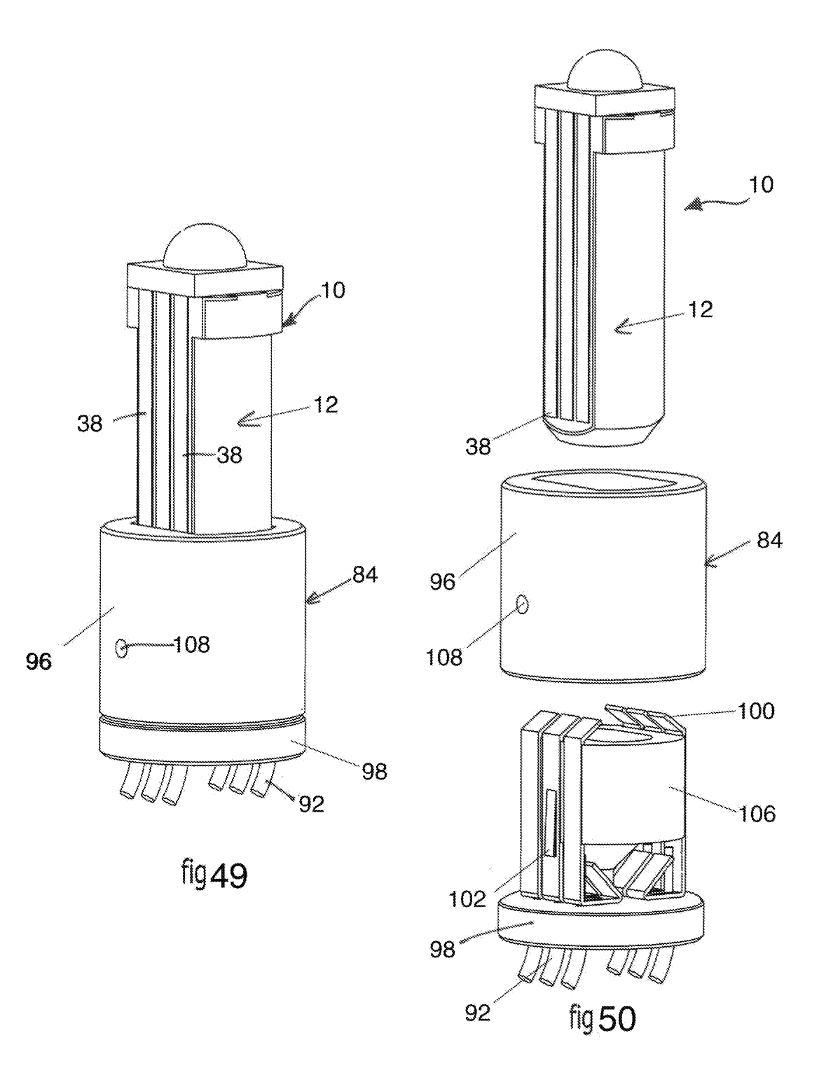

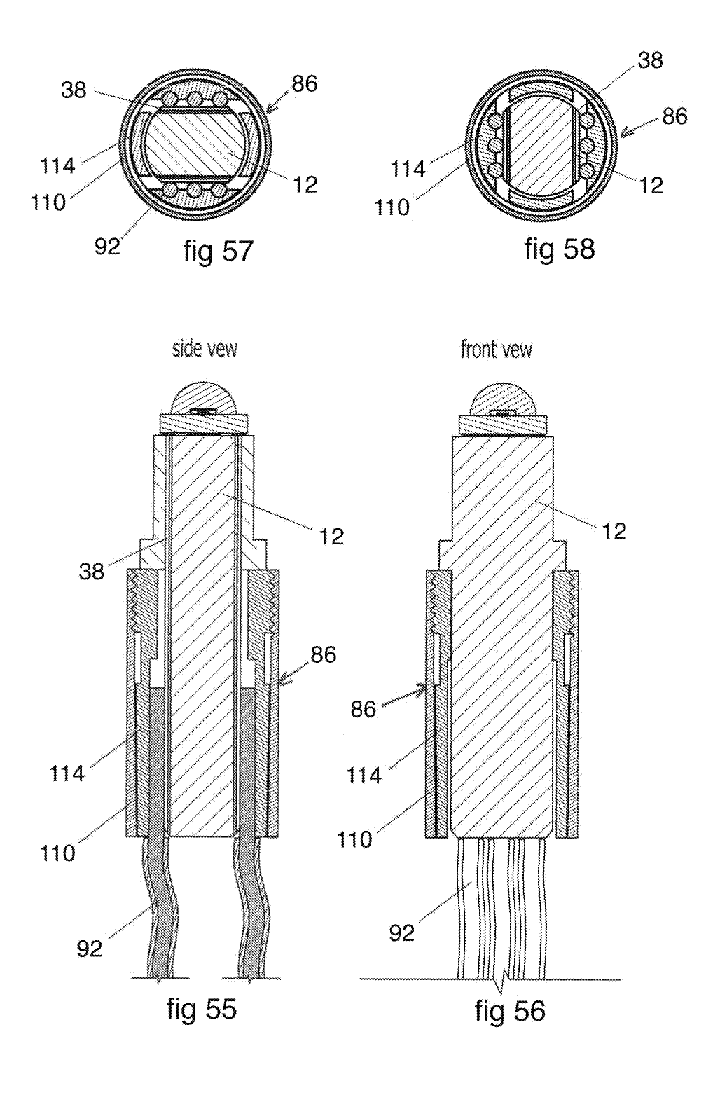

FIGS. 45 to 58 illustrate different terminal block and LED configurations. In particular, the terminal block 82 shown in FIGS. 45 to 48 is for a single light LED, whilst the terminal blocks 84 and 86 shown in FIGS. 49 to 58 are intended for RGB LED assemblies.

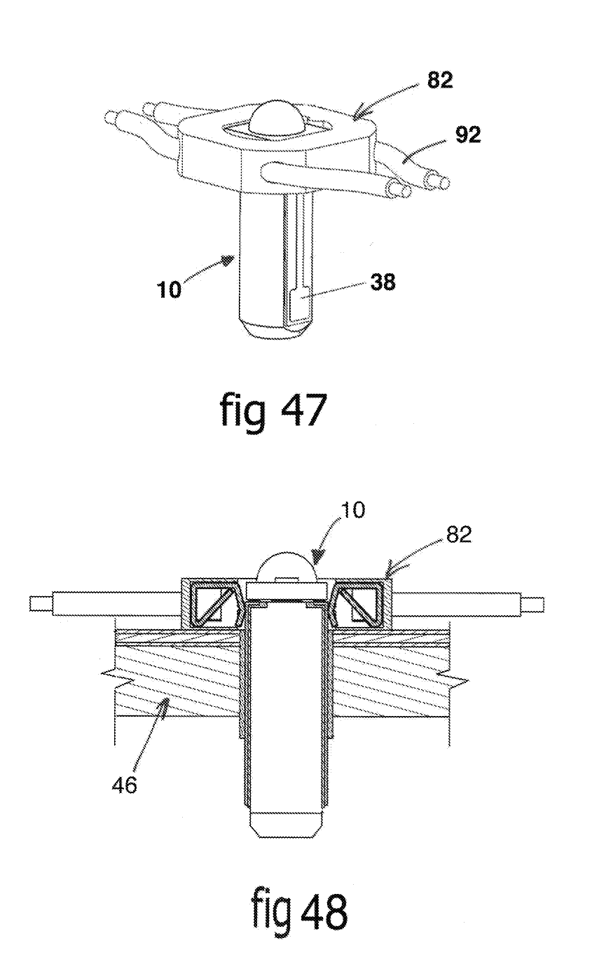

FIG. 45 shows a single light terminal block 82 without the LED assembly 10, and it can be seen that the device includes ridges 88 to clip the block onto the top of the LED and contacts 90 that connect to the circuit 38 on the rivet 12. The earlier described notch 44 on rivet 12 is adapted to engage the ridges 88 to secure the LED assembly in the terminal block 82. The terminal block 82 includes power/data cables 92 as is known in the art. FIG. 46 shows in detail how the contacts 90 are moveable so as to cause contact between clips 94 and the power/data cables 92 when the assembly 10 engages the block 84. FIG. 47 illustrates these components when assembled. FIG. 48 shows the assembled components affixed to a heat sink 48.

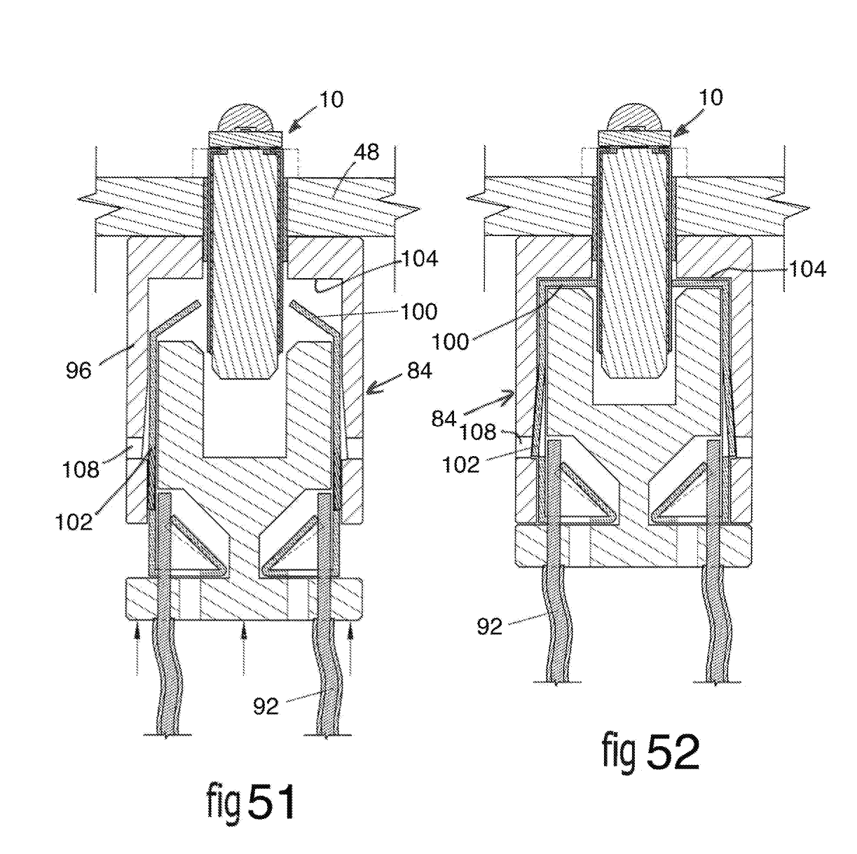

FIG. 49 shows a RGB LED assembly having three distinct circuit layers 38 housed on opposed sides of an RGB terminal block 84. As shown more clearly in FIGS. 50 to 52, the RGB terminal block 84 includes an outer housing 96 and a base 98 which supports clamping tabs 100 adapted to contact the three circuit layers 38 when the components are engaged. The clamping tabs 100 are in contact with respective data/power cables 92 at their lower ends. When the housing 96 is pushed down over the clamping tabs 100 towards the base 98, a biased sleeve 102 associated with one of the clamping tabs 100 is pushed inwards, until the housing 96 is fully inserted and the sleeve is able to snap back outwards again thereby locking the housing 96 in place. When the housing and the base are engaged like so, an internal shoulder 104 of the housing presses down against the top of the clamping tabs, and in combined action with inner housing 106 causes them to make contact with the circuit layers 38 (as shown clearly in FIG. 52). To disengage the housing, one simply needs to press the biased sleeve 102 using an appropriate tool through the aperture 108 in the side of the housing. FIGS. 51 and 52 also illustrate the use of a heat sink 48.

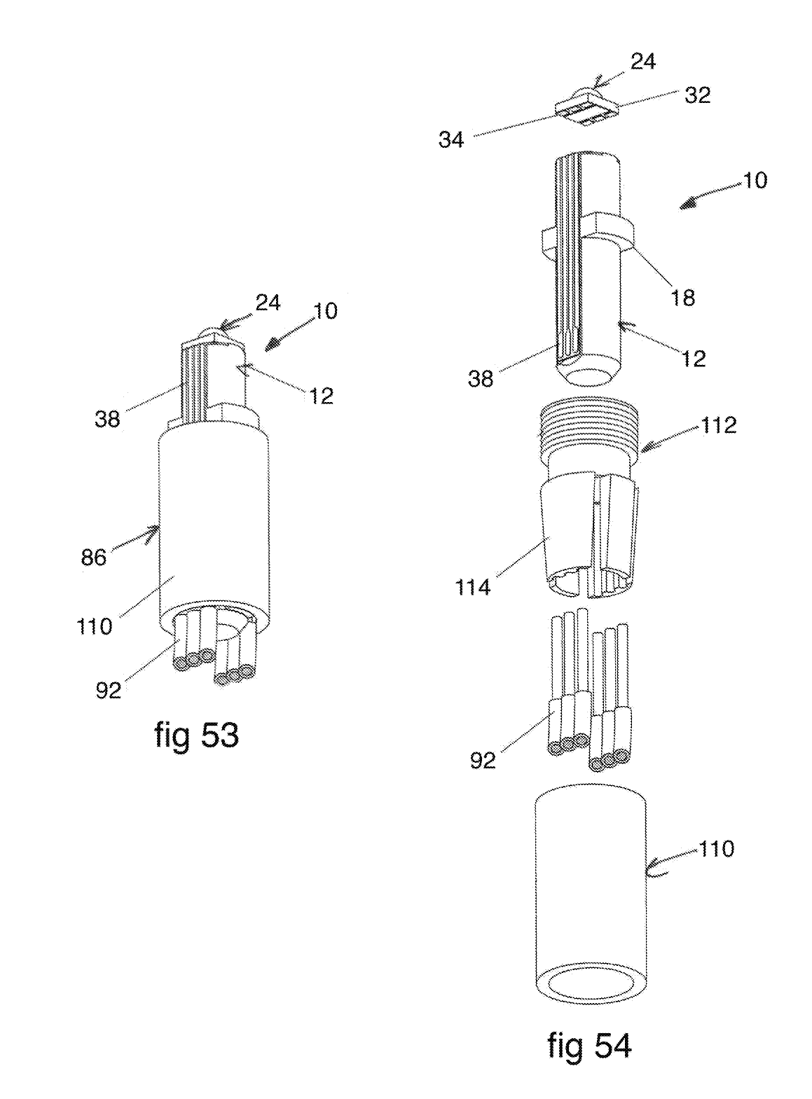

The terminal block embodiment shown in FIGS. 53 to 58 work on the same principles as the above described embodiments in that when the terminal block 86 is fully engaged with the LED assembly, an electrical connection is formed between the cables 92 and the circuit layers 38, and when disengaged, the connection is broken. The difference resides in the way in which this connection occurs. In this embodiment, the block 86 includes an outer housing 110 and an inner housing 112 which are engageable by threaded connection, the outer housing 110 including inner converging walls at a lower portion thereof and the inner housing 112 including inwardly moveable panel sleeves 114. These components are configured such that as the inner housing 112 is screwed into the outer housing, the converging walls cause the sleeves to move inwardly and thereby cause the cables housed therein to also move inwardly and make contact with the conductive layers 38 of the inserted rivet 12. As is also shown, the LED board 32 includes three solder pads 34 which correspond with the three circuit layers 38, and the shoulder 18 is shifted further down along the body of the rivet MCPCB 12.

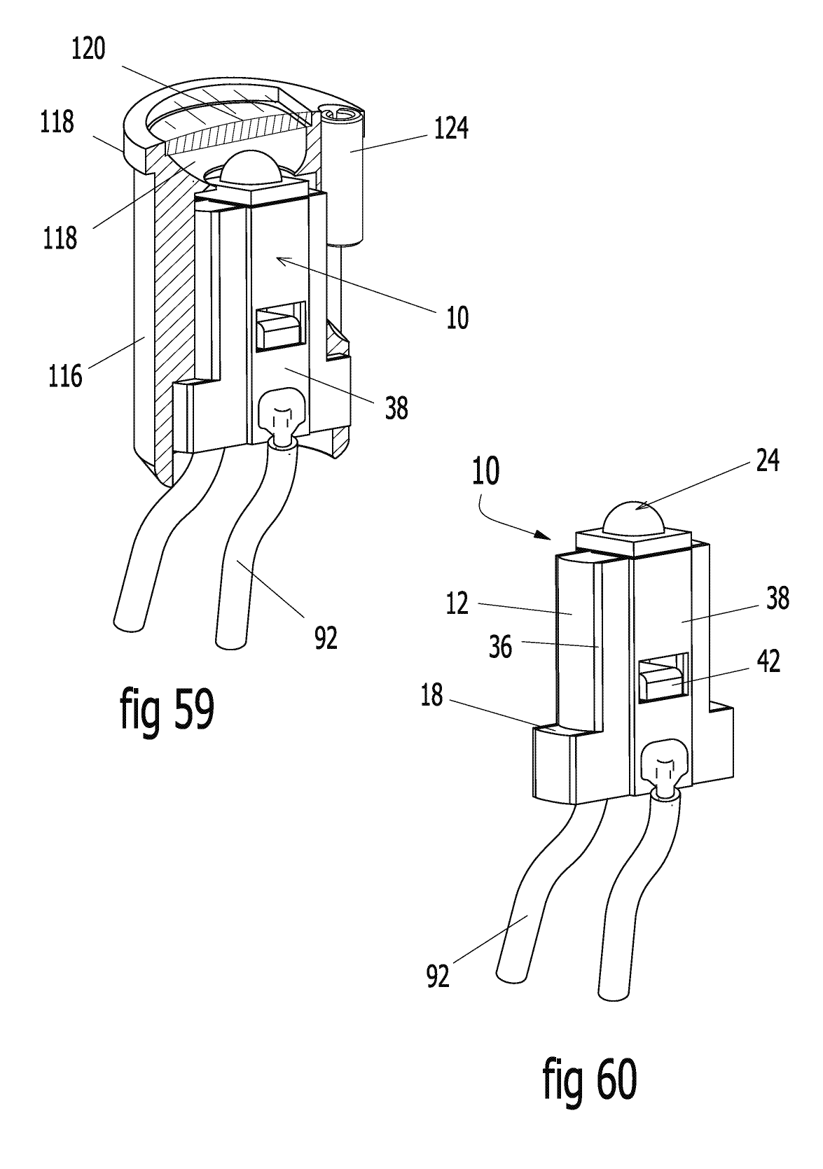

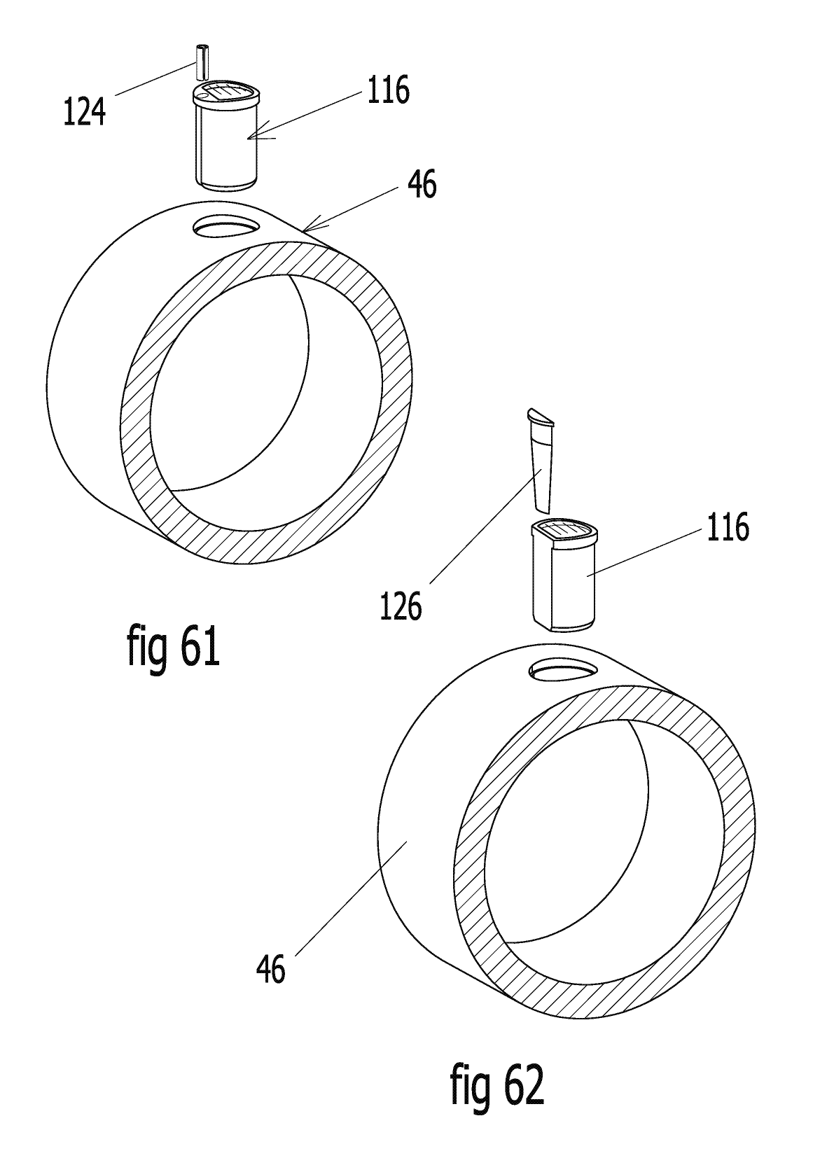

FIGS. 59 to 62 illustrate yet another way the LED assembly 10 could be used. The LED assembly 10 is housed in a puck 116 as shown in FIG. 59. In the embodiments shown, the puck 116 is in the form of a light device including a reflector 118 and a reflector cover 120 as shown in FIG. 59. The LED assembly 10, which is shown on its own in FIG. 60, can be secured in the puck 116 by any known means including in the configuration shown in the drawings. The puck is able to be inserted into various shaped heat sinks, including the handrail 46 shown in FIGS. 61 and 62, but not limited thereto. The shoulder 122 on the lighting device helps to locate the device in the wall of the pipe 46.

There is shown two means of fixing the device into the pipe. The first is shown in FIGS. 59 to 61 and is in the form of a compressible rollpin 124 adapted to push between the puck and the wall of the pipe to hold it in place. The roll pin 124 is pushed flush with the top face of the puck. The second means is shown in FIG. 62 and utilises a wedge 126 which pushes between the puck and the wall of the pipe to hold it in place, completing the cylindrical shape of the puck when pushed flushed to the puck face.

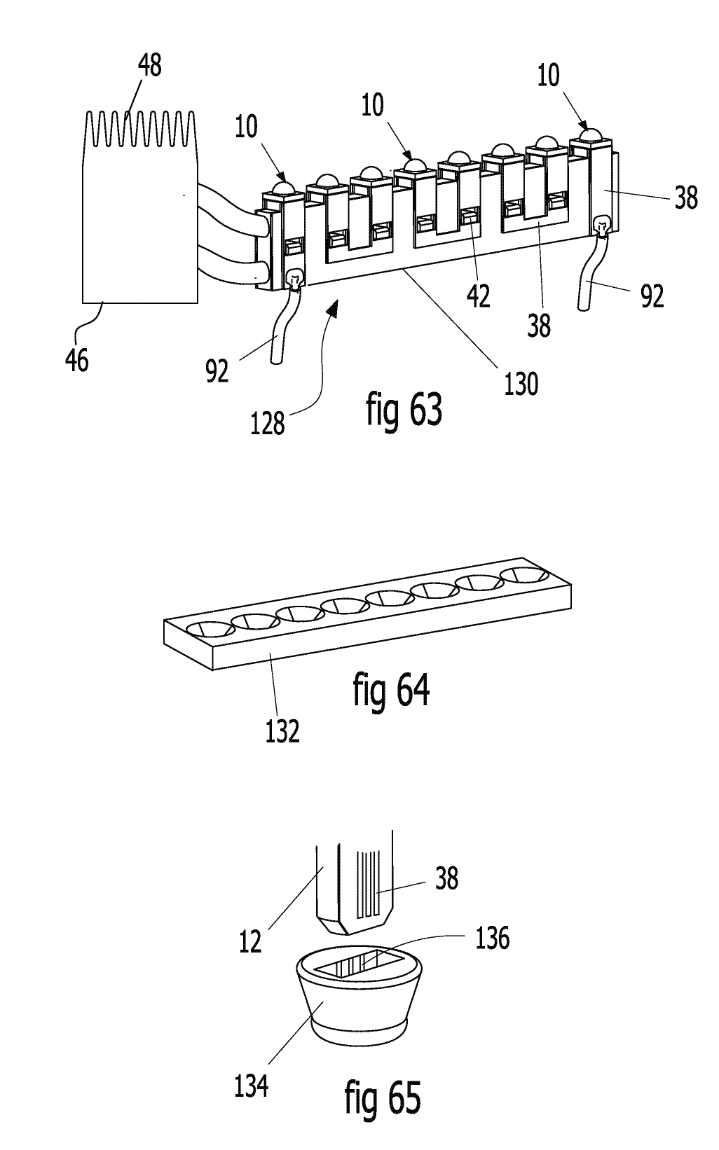

FIG. 63 illustrates an apparatus 128 including a plurality of LED assemblies 10, a heat pipe 130, and a heat sink 46. The heat sink 46 is to remove the heat at a distance from the LED assemblies 10. The heat pipe 130 has a fluid in it which interacts with the LED assemblies in a manner which causes heat to be absorbed by the fluid, the heated fluid then being cycled to the heat sink to thereby flush heat away from the LED assemblies. A reflector 132 suitable for use with the apparatus of FIG. 63 is shown in FIG. 64. The reflector can be used to focus the light from the LED assembly and insulate the radiant heat which emanates from the LED assemblies.

FIG. 65 illustrates a yet further embodiment in the form of a power connecting junction 134 adapted to clip on to the bottom of a MCPCB rivets 12, the junction including along an inner surface conductive layers 136 adapted to contact the conductive layers 38 along the rivet 12 to complete/connect a circuit.

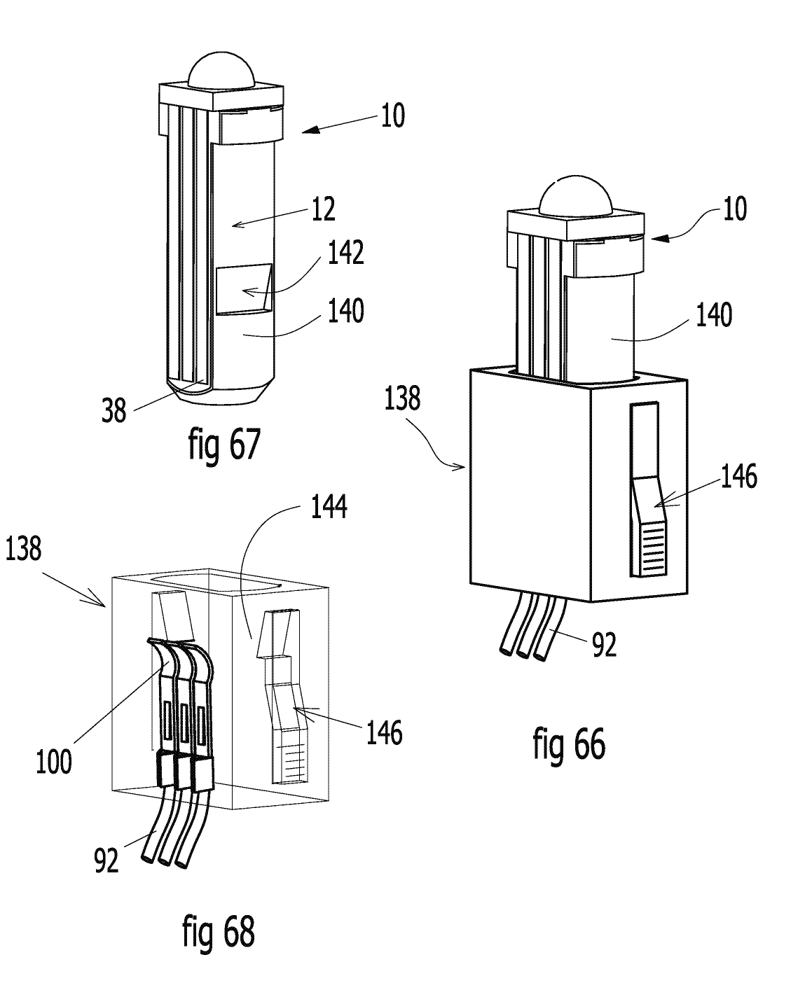

FIGS. 66 to 68 illustrate yet another way a LED assembly 10 of the present invention could be fixed inside a terminal block 138. In this embodiment, the MCPCB rivet 12 includes on one of its faces 140 a notch 142 which is engageable by an internal plug 144 associated with an upper portion of tab 146. The skilled addressee would realise that because the plug 144 is biased into a position such that it extends inside notch 142, it will engage the notch 142 when the assembly 10 is inserted sufficiently deeply inside the block 138. To then release the assembly 10, one would simply press the lower portion of the tab 146 which is configured such that in doing so, the upper portion and hence the plug 144 shifts outwardly and disengages the notch 142. As per previous embodiments, the terminal block includes internal clamping tabs 100 which engage the conductive layers 38 of the rivet 12 once inserted.

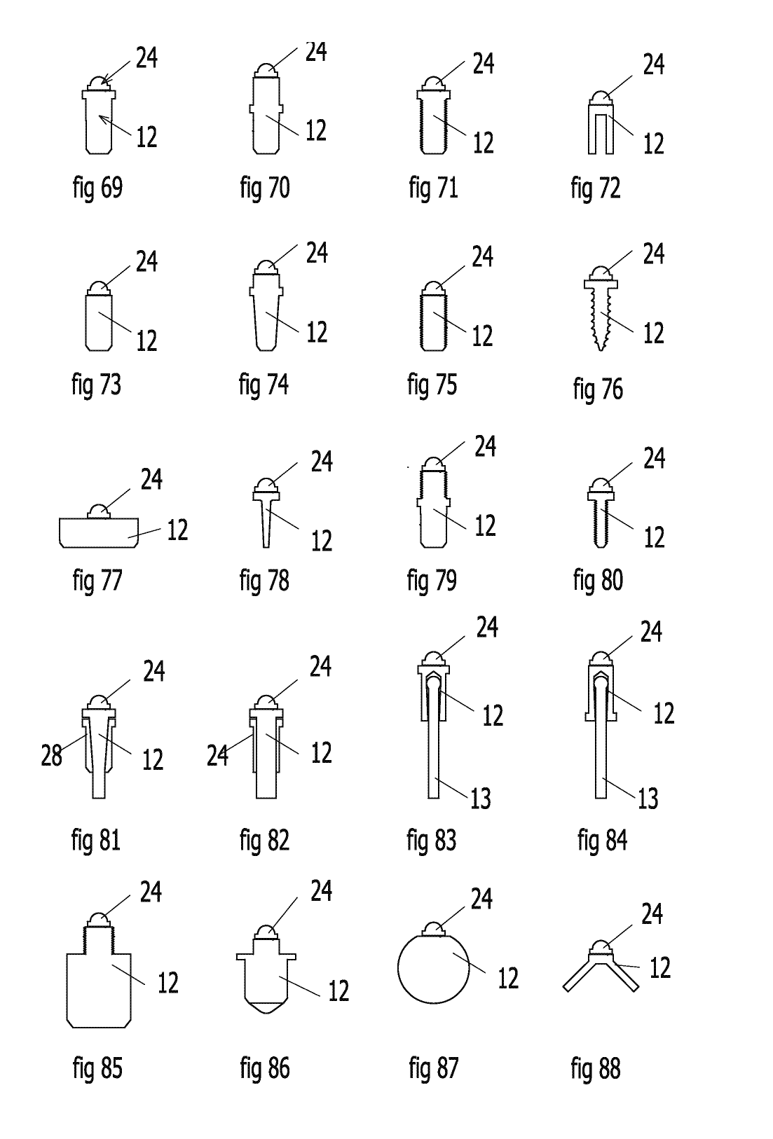

Finally, FIGS. 69 to 88 illustrate examples of possible shapes of LED assemblies including MCPCB's in the shape of rivets, screws, and other mechanical fasteners. For the purpose of brevity, these are not each described in detail.

The present invention is not intended to be limited use of just a light emitting diode (LED), silicon-based LED, silicon sub-mounted LED, or an LED made of any type of material. It could equally well be a solid state laser, an organic light-emitting diode, a polymer light-emitting diode, or another solid state light emitting device. It could also be a non-solid state light emitting device, for example, a non-solid state laser, a gaseous discharge light source (e.g., high-intensity dithe scharge), an electric arc light source (e.g., arc lamp), or any other component that would benefit from this system.

The MCPCB rivet body 12 is preferably made from sheet copper punched to shape, however, other materials and/or processes could also be used, including silver, aluminium, or any good thermal conductive material. The manufacturing processes could consist of, but is not limited to, bar machining, forging, or the use of pressure die cast processes.

Further advantages and improvements may very well be made to the present invention without deviating from its scope. Although the invention has been shown and described in what is conceived to be the most practical and preferred embodiment, it is recognized that departures may be made therefrom within the scope and spirit of the invention, which is not to be limited to the details disclosed herein but is to be accorded the full scope of the claims so as to embrace any and all equivalent devices and apparatus.

In any claims that follow and in the summary of the invention, except where the context requires otherwise due to express language or necessary implication, the word “comprising” is used in the sense of “including”, i.e. the features specified may be associated with further features in various embodiments of the invention.

I claim:

1. A method of opening a communications channel between a first and a second person, comprising the steps of:
receiving a date of birth from said first and said second person;
polling said first and said second person, and receiving answers for said first and said second person;
determining a Myers-Briggs Type Indicator (MBTI) for said first and said second person based on said answers;
determining a Chinese zodiac sign corresponding to said first and said second person, based on said received date of birth;
determining a Western astrological sign corresponding to said first and said second person, based on said received date of birth;
receiving at least one attribute characteristic of said first and said second person, and
receiving at least one limiting attribute required of a person from said first and said second person;
exhibiting to said first person, information about said second person if a weighted ranking of said MBTI, said Chinese zodiac, and said western astrology are determined to be above a compatibility threshold, and said second person comprises said limiting attributes required of said first person; and
providing a communication channel between said first and said second person, based on an expressed desire to communicate from said first person to said second person.

2. The method of claim 1, wherein said limiting attribute is a combination of age and location.

3. The method of claim 2, wherein said limiting attribute further comprises a limitation by distance between said first and said second party.

4. The method of claim 3, wherein said limiting attribute further comprises a limitation by personality type selected by said first or said second party.

5. The method of claim 1, wherein said characteristic attributes further comprise an interest, by each said party, in a particular relationship type, wherein said relationship type is a romantic partnership or a friendship.

6. The method of claim 1, wherein said characteristic attributes further comprise an interest, by each said individual, in a particular relationship type, wherein said relationship type is a business relationship.

7. The method of claim 1, wherein a match for parties is suggested based on a weighted average of compatibility of said Chinese zodiac and said western astrology and either said Chinese zodiac or said western astrology is given more weight based on a greater amount of communication from said first party in prior provided matches where a first zodiac type matched and a second zodiac type failed to match.

8. The method of claim 1, wherein a match is suggested when any two of said MBTI, said Chinese zodiac, and said western astrology match completely, and the third matches based on a single data point of matching with other data points of said third item being non-matched.

9. The method of claim 1, wherein, when a weighted average of compatibility between said western astrology and said Chinese zodiac is low compared to a predefined threshold or absence, then a match is suggested based on said western zodiac.

10. The method of claim 1, wherein individuals are of the same type according to said MBTI, and a weighted average of compatibility between a western astrology and Chinese zodiac is low compared to a predefined threshold, then a match is suggested based on said MBTI compatibility rating.

11. The method of claim 1, wherein a said zodiac matching is discarded only when said Myers-Briggs and other zodiac type match perfectly or near-perfectly, wherein near-perfectly is having, at most, one element or data point fail to match.

12. The method of claim 1, wherein a starting point of weighting of said zodiac and said Myers-Briggs is changed for future searches for matches of individuals based on:
providing at least one match based on each possible combination of two matching criteria selected from the group consisting of said MBTI, said western astrology, and said Chinese zodiac;
recording the number of said express desires to communicate for each said possible combination;
recording the length of communication between individuals using said communication channel for each said possible combination;
ranking combination matches based on said number of said express desires to communicate or said length of communication;
weighting said combinations, which have a higher said ranking, higher in said future searches.

13. A system of opening a communications channel between two individuals, comprising:
means for receiving a date of birth for each individual of said two individuals;
means for polling each said individual with questions, and receiving answers to said questions from each said individual;
means for determining an MBTI for each said individual based on said answers;
means for determining each said individual's Chinese zodiac, based on said received data of birth of each said individual;
means for determining each said individual's Western astrology, based on said received date of birth of each said individual;
means for receiving attributes characteristic of each said individual, and required attributes of another individual;
means for suggesting at least one match to a user based on said attributes characteristic of each said individual, said required attributes of another individual, compatibility according to said determined MBTI for each said individual, compatibility according to said Chinese and said Western zodiac;
means for receiving an indication by one said individual of accepting said at least one match; and
means for opening a communication channel between said one individual and another said individual associated with said accepted match.

14. A device configured to open a communications channel between two individuals based on criteria about the individuals, comprising:
an input and output user interface;
memory;
a storage device;
a network node receiving a date of birth for each individual of said two individuals and sending each said individual questions as well as receiving answers to said questions from each said individual;
a processor, configured to carry out instructions to determine a MBTI for each said individual based on said answers, determine each said individual's Chinese zodiac, based on said received date of birth, and determine a western zodiac for each said individual, based on said received date of birth;
whereby said network node further receives attributes characteristic of each said individual, and required attributes of another individual;
said processor carries out instructions to determine compatibility according to said determined MBTI for each said individual, and compatibility according to said Chinese and said western zodiac; and
said device receives an indication by one said individual of accepting a match, and opens a communication channel between said one individual and another said individual associated with said match.

15. (canceled)

16. (canceled)

17. The device of claim 14, wherein said characteristic attributes further comprise an interest, by each said individual, in a particular relationship type, wherein said relationship type is a romantic partnership or a friendship.

18. The device of claim 14, wherein said characteristic attributes further comprise an interest, by each said individual, in a particular relationship type, wherein said relationship type is a business relationship.

19. The device of claim 14, wherein a match for individuals is suggested based on a weighted average of compatibility of Chinese zodiac and western astrology.

20. The device of claim 14, wherein MBTI is weighted against Chinese zodiac and western astrology and highest compatibility rating of said two combinations is suggested as a match to said individuals.

21. The device of claim 14, wherein when a weighted average of compatibility between a western zodiac and Chinese zodiac is low compared to a predefined threshold or absent, then a match is suggested based on western zodiac.

22. The device of claim 14, wherein individuals are of the same type of MBTI and a weighted average of compatibility between a western astrology and Chinese zodiac is low compared to a predefined threshold, then a match is suggested based on said MBTI compatibility rating.
